(19) United States
(12) Patent Application Publication
(10) Pub. No.: US 2019/0062581 A1
(43) Pub. Date: Feb. 28, 2019

(54) INKJET PRINTING PEROVSKITE INK AND METHOD OF MAKING THE SAME

(71) Applicant: Shenzhen China Star Optoelectronics Semiconductor Display Technology Co., Ltd., Shenzhen City GD (CN)

(72) Inventor: Yunan Zhang, Shenzhen City (CN)

(21) Appl. No.: 15/579,932

(22) PCT Filed: Nov. 27, 2017
(86) PCT No.: PCT/CN2017/113034

§ 371 Date: Dec. 5, 2017

(30) Foreign Application Priority Data
Aug. 25, 2017 (CN) 201710744068.4

(51) Int. Cl. C09D 11/50; C09D 11/52; C09D 11/322; C09D 11/36; C09D 11/037; C09D 11/033; C09K 11/06; H01L 51/00

(52) U.S. Cl. CPC C09D 11/50; C09D 11/52; C09D 11/322; C09D 11/36; H01L 51/5012; C09D 11/033; C09K 11/06; H01L 51/0077; C09D 11/037

(57) ABSTRACT

The present invention provides an inkjet printing perovskite ink and a method of making the same. The manufacturing process of the method of making an inkjet printing perovskite ink of the present invention is simple; the derived inkjet printing perovskite ink has a certain viscosity, surface tension, and volatile performance, which is able to meet the inkjet printing process requirements, to achieve perovskite luminescent layer inkjet printing. The inkjet printing perovskite ink of the present invention is derived by the above method, which is able to meet the inkjet printing process requirements, to achieve perovskite luminescent layer inkjet printing.

### BACKGROUND OF THE INVENTION

### Field of Invention

The present invention relates to the field of the display technology, and more particularly to an inkjet printing perovskite ink and a method of making the same.

### Description of Prior Art

The ABX3-based perovskite material is named after the calcium titanate (CaTiO3) compound when firstly found in perovskites. The perovskite structure is characterized by a co-vertex connection of an X octahedron centered on the B-positioned cation and being embedded in a tetragon with the A-positioned ions as the apex. The A-positioned cations and B-positioned cations can be occupied by a single ion or a variety of ions. According to the types and the ionic radii of the A-positioned cations and B-positioned cations, perovskite materials with different microstructures and different physical properties can be constructed.

The structures and physical properties of organic/inorganic hybrid perovskite (OIHP) materials were first reported by Weber (Naturforsch. 1978, 33b, 1443). It can be seen as alternating stacking of organic groups and inorganic moieties. The organic-inorganic hybrid perovskite materials are solution-processable semiconductor materials with characteristics of low cost, high carrier mobility and large optical absorption coefficient. In recent years, organic-inorganic hybrid perovskite materials have very good performance in the field of solar cells. Meanwhile, the organic-inorganic hybrid perovskite materials have the characteristics of light emission with adjustable wavelength and narrow emission spectrum, and also have great potential in the fields of electroluminescence, laser and display. The organic-inorganic hybrid perovskite materials have the advantages of both the organic and inorganic semiconductor materials and are suitable for organic semiconductor material solution processing and large-area film-forming preparation process. In addition, the organic-inorganic hybrid perovskite materials also have the advantages of low defect density and high luminous efficiency, good color purity and other advantages.

The organic-inorganic hybrid perovskite materials can be dispersed in a solvent to prepare an ink. Specifically, the perovskite luminescent film can be prepared by printing, transfer-printing, spin coating and the like. Among them, inkjet printing technology can precisely deposit the organic-inorganic hybrid perovskite materials in the predetermined positions and deposit it to form a precise pixel film, which is favorable for application to the manufacturing of a large-size colored perovskite light emitting diode (PeLED) for reducing costs. However, the ink jet printing apparatus and the printing process have certain requirements on the ink. In order to make the ink suitable for the ink jet printing technology, the solvent components, the viscosity and the surface tension of the ink are generally adjusted. Therefore, a perovskite ink suitable, for the ink jet printing apparatus and perovskite printing ink printing process conditions needs to be improved.

### SUMMARY OF THE INVENTION

An object of the present invention is to provide a method of making an inkjet printing perovskite ink, the manufacturing process is simple, the derived inkjet printing perovskite ink has a certain viscosity, surface tension, and volatile performance, which is able to meet the inkjet printing process requirements, to achieve perovskite luminescent layer inkjet printing.

An object of the present invention is to further provide an inkjet printing perovskite ink, which is able to meet the inkjet printing process requirements, to achieve perovskite luminescent layer inkjet printing.

In order to achieve the object, the present invention provides a method of making an inkjet printing perovskite ink, which comprises:

A perovskite material and a solvent are provided. The perovskite material is dispersed in the solvent, to derive a perovskite solution.

Under stirring function, a viscosity modifier and a surface tension modifier are added to the perovskite solution. After stirring uniformly, an inkjet printing perovskite ink is obtained.

The perovskite material is an organic-inorganic doped perovskite material. The structural general formula of the organic-inorganic doped perovskite material is CH₃NH₃PbX₃, where X=Cl, Br, or I.

The solvent is selected from the group consisting of at least one alkane or aromatic hydrocarbon compound, at least one alcoholic compound, and at least one high boiling point solvent.

The alcohol compound is selected from the group consisting of one or more of monohydric alcohols and polyhydric alcohols.

The high-boiling solvent is selected from the group consisting of one or more of an ether compound and an ester compound, and the high-boiling solvent has a boiling point of more than 200° C.

The surface tension modifier is selected from the group consisting of one or more of imidazole and its derivatives, phenol, and hydroquinone. The viscosity modifier is selected from the group consisting of one or more of alcohols, ethers, esters, phenols, and amines.

In the inkjet printing perovskite ink. A mass percentage of the perovskite material is 0.1% to 30%. A mass percentage of the solvent is 10% to 99.99%. A mass percentage of the surface tension modifier is 0.1% to 5%. A mass percentage of the viscosity modifier is 0.1% to 5%.

The present invention further provides an inkjet printing perovskite ink, which comprises a solvent and a perovskite material dispersed in the solvent, a viscosity modifier and a surface tension modifier.

The perovskite material is an organic-inorganic doped perovskite material. The structural general formula of the organic-inorganic doped perovskite material is CH₃NH₃PbX₃, where X=Cl, Br, or I.

The solvent is selected from the group consisting of at least one alkane or aromatic hydrocarbon compound, at least one alcoholic compound, and at least one high boiling point solvent.

The alcohol compound is selected from the group consisting of one or more of monohydric alcohols and polyhydric alcohols.

The high-boiling solvent is selected from the group consisting of one or more of an ether compound and an ester compound, and the high-boiling solvent has a boiling point of more than 200° C.

The surface tension modifier is selected from the group consisting of one or more of imidazole and its derivatives, phenol, and hydroquinone. The viscosity modifier is selected from the group consisting of one or more of alcohols, ethers, esters, phenols, and amines.

In the inkjet printing perovskite ink. A mass percentage of the perovskite material is 0.1% to 30%. A mass percentage of the solvent is 10% to 99.99%. A mass percentage of the surface tension modifier is 0.1% to 5%. A mass percentage of the viscosity modifier is 0.1% to 5%.

The present invention further provides a method of making an inkjet printing perovskite ink, which comprises:

A perovskite material and a solvent are provided. The perovskite material is dispersed in the solvent, to derive a perovskite solution.

Under stirring function, a viscosity modifier and a surface tension modifier are added to the perovskite solution. After stirring uniformly, an inkjet printing perovskite ink is obtained.

Wherein the perovskite material is an organic-inorganic doped perovskite material. The structural general formula of the organic-inorganic doped perovskite material is CH₃NH₃PbX₃, where X=Cl, Br, or I.

The solvent is selected from the group consisting of at least one alkane or aromatic hydrocarbon compound, at least one alcoholic compound, and at least one high boiling point solvent.

Wherein the alcohol compound is selected from the group consisting of one or more of monohydric alcohols and polyhydric alcohols.

The high-boiling solvent is selected from the group consisting of one or more of an ether compound and an ester compound, and the high-boiling solvent has a boiling point of more than 200° C.

Wherein the surface tension modifier is selected from the group consisting of one or more of imidazole and its derivatives, phenol, and hydroquinone. The viscosity modifier is selected from the group consisting of one or more of alcohols, ethers, esters, phenols, and amines.

Wherein in the inkjet printing perovskite ink. A mass percentage of the perovskite material is 0.1% to 30%. A mass percentage of the solvent is 10% to 99.99%. A mass percentage of the surface tension modifier is 0.1% to 5%. A mass percentage of the viscosity modifier is 0.1% to 5%.

The beneficial effects of the present invention are: The manufacturing process of the method of making an inkjet printing perovskite ink of the present invention is simple; the derived inkjet printing perovskite ink has a certain viscosity, surface tension, and volatile performance, which is able to meet the inkjet printing process requirements, to achieve perovskite luminescent layer inkjet printing. The inkjet printing perovskite ink of the present invention is derived by the above method, which is able to meet the inkjet printing process requirements, to achieve perovskite luminescent layer inkjet printing.

For further understanding of the features and technical contents of the present invention, reference should be made to the following detailed description and accompanying drawings of the present invention. However, the drawings are for reference only and are not intended to limit the present invention.

### BRIEF DESCRIPTION OF THE DRAWINGS

The technical solutions of the present invention and other beneficial effects will be apparent from the following detailed description of specific embodiments of the present invention with reference to the accompanying drawings.

In drawings:

FIG. 1 is a flow chart of a method of making an inkjet printing perovskite ink according to the present invention.

### DETAILED DESCRIPTION OF THE PREFERRED EMBODIMENTS

The technical means and the effects thereof will be further described with reference to the preferred embodiments of the present invention and their accompanying drawings.

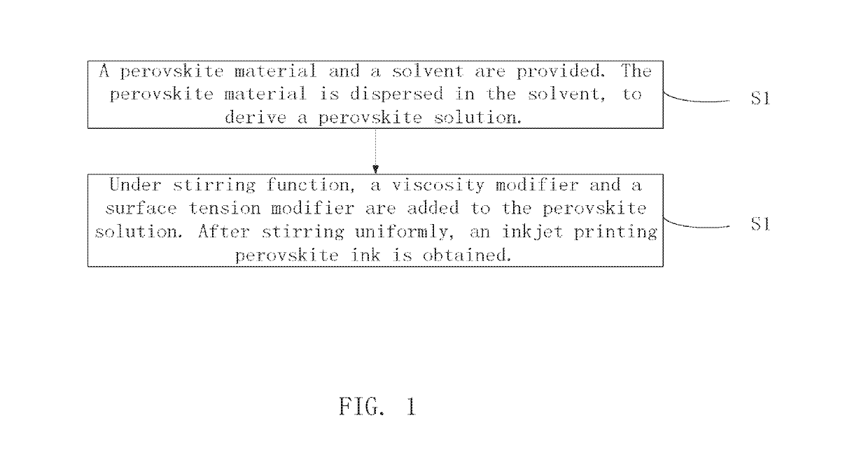

Please refer to FIG. 1, which is a flow chart of a method of making an inkjet printing perovskite ink according to the present invention which comprises:

Step S1, a perovskite material and a solvent are provided. The perovskite material is dispersed in the solvent, to derive a perovskite solution.

Specifically, the perovskite material is an organic-inorganic doped perovskite material. The structural general formula of the organic-inorganic doped perovskite material is CH₃NH₃PbX₃, where X=Cl, Br, or I. With the selection of halogen anions X in the perovskite material, different colors of the luminescent light can be adjusted.

Preferably, the perovskite material has a quantum dot size to have better luminescent properties.

Specifically, the solvent is selected from the group consisting of at least one alkane or aromatic hydrocarbon compound, at least one alcoholic compound, and at least one high boiling point solvent. The solvent is used for dispersing the perovskite material while also regulating the physical properties of the inkjet printing perovskite ink derived subsequently, to meet the needs of inkjet printing.

Specifically, the alcohol compound is selected from the group consisting of one or more of monohydric alcohols and polyhydric alcohols.

Specifically, the high-boiling solvent is selected from the group consisting of one or more of an ether compound and an ester compound, and the high-boiling solvent has a boiling point of more than 200° C., which is beneficial for improving the boiling point of the inkjet printing perovskite derived subsequently, to ensure that the ink will not be dried up too quickly during inkjet printing and improve the stability of inkjet printing process.

Step S2, under stirring function, a viscosity modifier and a surface tension modifier are added to the perovskite solution. After stirring uniformly, an inkjet printing perovskite ink is obtained.

Specifically, the surface tension modifier is selected from the group consisting of one or more of imidazole and its derivatives, phenol, and hydroquinone.

Specifically, the viscosity modifier is selected from the group consisting of one or more of alcohols, ethers, esters, phenols, and amines.

Specifically, the method of making an inkjet printing perovskite ink according of the present invention can further comprise: A co-solvent and a surfactant are added to the inkjet printing perovskite ink to further adjust the surface tension of the inkjet printing perovskite ink.

Specifically, in the inkjet printing perovskite ink. A mass percentage of the perovskite material is 0.1% to 30%. A mass percentage of the solvent is 10% to 99.99%. A mass percentage of the surface tension modifier is 0.1% to 5%. A mass percentage of the viscosity modifier is 0.1% to 5%.

The manufacturing process of the method of making an inkjet printing perovskite ink of the present invention is simple; the derived inkjet printing perovskite ink has a certain viscosity, surface tension, and volatile performance, which is able to meet the inkjet printing process requirements, to achieve perovskite luminescent layer inkjet printing.

Based on the above manufacturing process of the method of making an inkjet printing perovskite ink, the present invention further provides an inkjet printing perovskite ink, which comprises a solvent and a perovskite material dispersed in the solvent, a viscosity modifier and a surface tension modifier.

The inkjet printing perovskite ink of the present invention is derived by the above method, which is able to meet the inkjet printing process requirements, to achieve perovskite luminescent layer inkjet printing.

Specifically, the perovskite material is an organic-inorganic doped perovskite material. The structural general formula of the organic-inorganic doped perovskite material is CH₃NH₃PbX₃, where X=Cl, Br, or I. Specifically, with the selection of halogen anions X in the perovskite material, different colors of the luminescent light can be adjusted.

Preferably, the perovskite material has a quantum dot size to have better luminescent properties.

Specifically, the solvent is selected from the group consisting of at least one alkane or aromatic hydrocarbon compound, at least one alcoholic compound, and at least one high boiling point solvent. The solvent is used for dispersing the perovskite material while also regulating the physical properties of the inkjet printing perovskite ink, to meet the needs of inkjet printing.

Specifically, the alcohol compound is selected from the group consisting of one or more of monohydric alcohols and polyhydric alcohols.

Specifically, the high-boiling solvent is selected from the group consisting of one or more of an ether compound and an ester compound, and the high-boiling solvent has a boiling point of more than 200° C., which is beneficial for improving the boiling point of the inkjet printing perovskite, to ensure that the ink will not be dried up too quickly during inkjet printing and improve the stability of inkjet printing process.

Specifically, the surface tension modifier is selected from the group consisting of one or more of imidazole and its derivatives, phenol, and hydroquinone.

Specifically, the viscosity modifier is selected from the group consisting of one or more of alcohols, ethers, esters, phenols, and amines.

Specifically, the inkjet printing perovskite ink can further comprises a co-solvent and a surfactant to further adjust the surface tension of the inkjet printing perovskite ink.

Specifically, in the inkjet printing perovskite ink. A mass percentage of the perovskite material is 0.1% to 30%. A mass percentage of the solvent is 10% to 99.99%. A mass percentage of the surface tension modifier is 0.1% to 5%. A mass percentage of the viscosity modifier is 0.1% to 5%.

The inkjet printing perovskite ink of the present invention has a certain viscosity, surface tension, and volatile performance, which is able to meet the inkjet printing process requirements, to achieve perovskite luminescent layer inkjet printing.

As mentioned above, the present invention provides an inkjet printing perovskite ink and a method of making the same. The manufacturing process of the method of making an inkjet printing perovskite ink of the present invention is simple; the derived inkjet printing perovskite ink has a certain viscosity, surface tension, and volatile performance, which is able to meet the inkjet printing process requirements, to achieve perovskite luminescent layer inkjet printing. The inkjet printing perovskite ink of the present invention is derived by the above method, which is able to meet the inkjet printing process requirements, to achieve perovskite luminescent layer inkjet printing.

As mentioned above, those of ordinary skill in the art, without departing from the spirit and scope of the present invention, can make various kinds of modifications and variations to the present invention. Therefore, all such modifications and variations are intended to be included in the protection scope of the appended claims of the present invention.

What is claimed is:

1. A method of making an inkjet printing perovskite ink, comprising:
providing a perovskite material and a solvent, dispersing the perovskite material in the solvent, to derive a perovskite solution;
under stirring function, adding a viscosity modifier and a surface tension modifier to the perovskite solution, after stirring uniformly, obtaining an inkjet printing perovskite ink.

2. The method of making an inkjet printing perovskite ink according to claim 1, wherein the perovskite material is an organic-inorganic doped perovskite material, the structural general formula of the organic-inorganic doped perovskite material is CH₃NH₃PbX₃, where X=Cl, Br, or I;
the solvent is selected from the group consisting of at least one alkane or aromatic hydrocarbon compound, at least one alcoholic compound, and at least one high boiling point solvent.

3. The method of making an inkjet printing perovskite ink according to claim 2, wherein the alcohol compound is selected from the group consisting of one or more of monohydric alcohols and polyhydric alcohols;
the high-boiling solvent is selected from the group consisting of one or more of an ether compound and an ester compound, and the high-boiling solvent has a boiling point of more than 200° C.

4. The method of making an inkjet printing perovskite ink according to claim 1, wherein the surface tension modifier is selected from the group consisting of one or more of imidazole and its derivatives, phenol, and hydroquinone; the viscosity modifier is selected from the group consisting of one or more of alcohols, ethers, esters, phenols, and amines.

5. The method of making an inkjet printing perovskite ink according to claim 1, wherein in the inkjet printing perovskite ink, a mass percentage of the perovskite material is 0.1% to 30%; a mass percentage of the solvent is 10% to 99.99%; a mass percentage of the surface tension modifier is 0.1% to 5%; a mass percentage of the viscosity modifier is 0.1% to 5%.

6. An inkjet printing perovskite ink, comprising a solvent and a perovskite material dispersed in the solvent, a viscosity modifier and a surface tension modifier.

7. The inkjet printing perovskite ink according to claim 6, wherein the perovskite material is an organic-inorganic doped perovskite material, the structural general formula of the organic-inorganic doped perovskite material is CH₃NH₃PbX₃, where X=Cl, Br, or I;
the solvent is selected from the group consisting of at least one alkane or aromatic hydrocarbon compound, at least one alcoholic compound, and at least one high boiling point solvent.

8. The inkjet printing perovskite ink according to claim 7, wherein the alcohol compound is selected from the group consisting of one or more of monohydric alcohols and polyhydric alcohols;
the high-boiling solvent is selected from the group consisting of one or more of an ether compound and an ester compound, and the high-boiling solvent has a boiling point of more than 200° C.

9. The inkjet printing perovskite ink according to claim 6, wherein the surface tension modifier is selected from the group consisting of one or more of imidazole and its derivatives, phenol, and hydroquinone; the viscosity modifier is selected from the group consisting of one or more of alcohols, ethers, esters, phenols, and amines.

10. The inkjet printing perovskite ink according to claim 6, wherein in the inkjet printing perovskite ink, a mass percentage of the perovskite material is 0.1% to 30%; a mass percentage of the solvent is 10% to 99.99%; a mass percentage of the surface tension modifier is 0.1% to 5%; a mass percentage of the viscosity modifier is 0.1% to 5%.

11. A method of making an inkjet printing perovskite ink, comprising:
providing a perovskite material and a solvent, dispersing the perovskite material in the solvent, to derive a perovskite solution;
under stirring function, adding a viscosity modifier and a surface tension modifier to the perovskite solution, after stirring uniformly, obtaining an inkjet printing perovskite ink;
wherein the perovskite material is an organic-inorganic doped perovskite material, the structural general formula of the organic-inorganic doped perovskite material is CH₃NH₃PbX₃, where X=Cl, Br, or I;
the solvent is selected from the group consisting of at least one alkane or aromatic hydrocarbon compound, at least one alcoholic compound, and at least one high boiling point solvent;
wherein the alcohol compound is selected from the group consisting of one or more of monohydric alcohols and polyhydric alcohols;
the high-boiling solvent is selected from the group consisting of one or more of an ether compound and an ester compound, and the high-boiling solvent has a boiling point of more than 200° C.;
wherein the surface tension modifier is selected from the group consisting of one or more of imidazole and its derivatives, phenol, and hydroquinone; the viscosity modifier is selected from the group consisting of one or more of alcohols, ethers, esters, phenols, and amines;
wherein in the inkjet printing perovskite ink, a mass percentage of the perovskite material is 0.1% to 30%; a mass percentage of the solvent is 10% to 99.99%; a mass percentage of the surface tension modifier is 0.1% to 5%; a mass percentage of the viscosity modifier is 0.1% to 5%.
